(19) United States
(12) Patent Application Publication
(10) Pub. No.: US 2024/0288526 A1
(43) Pub. Date: Aug. 29, 2024

(54) Systems and Methods for Robust Multi-Channel Image Reconstruction in MRI

(71) Applicant: The University of Hong Kong, Hong Kong (CN)

(72) Inventors: Ed Xuekui Wu, Hong Kong (CN); Jiahao Hu, Hong Kong (CN); Zheyuan Yi, Hong Kong (CN); Tze Lun Leong, Hong Kong (CN)

(73) Assignee: The University of Hong Kong, Hong Kong (CN)

(21) Appl. No.: 18/586,415

(22) Filed: Feb. 23, 2024

Related U.S. Application Data
(60) Provisional application No. 63/449,021, filed on Feb. 28, 2023.

(51) Int. Cl. G01R 33/56; G01R 33/48; G01R 33/561; G01R 33/58; G06T 11/00

(52) U.S. Cl. CPC G01R 33/5608; G01R 33/4824; G01R 33/5611; G01R 33/58; G06T 11/005; G06T 2210/41

(57) ABSTRACT

A method for hybrid-domain reconstruction of MRI images includes the steps of (A) extracting null-subspace bases of a calibration matrix from k-space coil calibration data to calculate image-domain spatial null maps (SNMs) and (B) reconstructing multi-channel images by solving an image-domain nulling system formed by SNMs that contain both coil sensitivity and finite image support information, thus circumventing the masking-related procedure and demonstrating a robust reconstruction.

### CROSS-REFERENCE TO RELATED PATENT APPLICATIONS

This application claims the benefit of priority under 35 U.S.C. Section 119(e) of U.S. Application No. 63/449,021, filed Feb. 28, 2024, which is incorporated herein by reference in its entirety.

### FIELD OF THE INVENTION

The present invention relates to multi-channel or parallel imaging reconstruction of MRI images, and more particularly to null space and hybrid-domain reconstruction.

### BACKGROUND OF THE INVENTION

Parallel imaging (PI) is widely used in clinical magnetic resonance imaging (MRI) to accelerate data acquisition or correct artifacts through the use of multiple receiving coils where each coil exhibits a unique spatial coil sensitivity map (CSM) [1-4]. PI reconstruction techniques generally fall into three classes: image-domain [4-8], k-space [9-20], and hybrid-domain categories [21], depending on where the coil sensitivity information is used to perform the reconstruction. The image-domain methods such as SENSE [4] utilize explicit knowledge of the CSMs. In theory, they can produce optimal least-square reconstruction if accurate CSMs are available [21-23]. The image-domain methods also provide the flexibility of incorporating “image priors,” such as image sparsity, to suppress noise amplification (e.g., through image-domain regularization) [24-26]. Image priors are merely prior information about the set of images. However, accurate CSMs are sometimes difficult to obtain in practice and their inaccuracies can cause noise amplification and artifacts in the reconstructed images [23-27]. The k-space reconstruction methods (e.g., GRAPPA [9] and ESPIRIT [18]) utilize local linear dependencies among k-space samples for reconstruction. They provide robust reconstruction through coil sensitivity autocalibration data, mitigating the problem of spatial mismatch between the coil sensitivity calibration and under-sampled data in SENSE reconstruction, e.g., due to motion. However, the k-space reconstruction methods cannot easily incorporate image priors for further improving reconstruction performance.

Among the k-space methods, PRUNO is a subspace based reconstruction method in which a k-space nulling system is formed by null-subspace bases of the calibration matrix [16]. PRUNO produces fewer residual artifacts with a limited autocalibration signal when compared with GRAPPA [16]. However, as shown in the original ESPIRIT study [21], PRUNO is computationally prohibitive in practice, and it cannot offer the flexibility of incorporating image priors as in image-domain reconstruction methods. As a hybrid-domain method, ESPIRIT extends the concept of subspace based reconstruction developed in PRUNO. It provides a more efficient and flexible approach in which the signal-subspace bases are extracted to derive coil sensitivity information for an extended SENSE based reconstruction [21]. By obtaining coil sensitivity information from subspace bases through eigen-decomposition, ESPIRIT bridges the gap between image-domain SENSE and k-space GRAPPA while retaining the benefits of both. However, ESPIRIT requires manually thresholding eigenvalues to mask the eigenvector maps to spatially define the image background region in order to minimize the noise propagation during image reconstruction. Thus, the optimal threshold is image-content dependent and often involves a trial-and-error selection. A sub-optimal threshold can undermine the reconstruction quality, e.g., causing noise increase and residual artifacts. In addition, ESPIRIT reconstruction is sensitive to the subspace cut-off selection, through which signal-subspace must be accurately separated from null-subspace. Inaccurate subspace division can lead to inaccurate coil sensitivity information and degrade the reconstruction performance. Stein's unbiased risk estimate (SURE) was recently developed to select the ESPIRIT's parameters automatically. It searches for the optimal parameters with minimum mean-square-error reconstruction in a data-driven manner and therefore avoids manually optimizing eigenvalue thresholding and subspace cut-off. However, this method is computationally demanding even though it employs strategies to alleviate the computational burden. Furthermore, since the optimal parameters are image content dependent and require an estimation for each single slice, SURE-based ESPIRIT reconstruction can become very time-consuming in practice, especially for dynamic imaging reconstruction.

As noted, PRUNO is a k-space PI reconstruction method in which a nulling system is derived using null-subspace bases [16]. A block-wise Hankel matrix called a calibration matrix A is constructed from k-space coil calibration data (FIG. 1A). The subspace bases are obtained by applying singular value decomposition (SVD) on the calibration matrix and selecting a cut-off to separate the signal-subspace V_{∥} and null-subspace V_{⊥}. In particular, central fully-sampled multi-channel k-space or coil sensitivity calibration data are vectorized to a block-wise Hankel matrix A. SVD is then performed on A to calculate singular vector matrix V. By setting a cut-off in V, signal-subspace V_{∥} and null-subspace V_{⊥} are separated. The columns in V_{∥} and V_{⊥} are signal- and null-subspace bases, respectively. For each multi-channel k-space local subset d in the calibration data, the k-space nulling system can be formed as:

$${F}^{H} d = 0 , where F = [ \begin{matrix}{f}_{11}^{null} & ⋯ & {f}_{1 n}^{null} \\ ⋮ & ⋮ & ⋮ \\ {f}_{{n}_{c} 1}^{null} & ⋯ & {f}_{{n}_{c} n}^{null}\end{matrix} ] and d = [ \begin{matrix}{d}_{1} \\ ⋮ \\ {d}_{{n}_{c}}\end{matrix} ] . \qquad ( 1 )$$

Here F is the nulling system matrix and F^{H} is the Hermitian matrix of F. fᵢⱼ^{null} represents each 2D null-subspace convolution kernel that is transformed from the jth null-subspace basis vⱼ (the jth column in V_{⊥}) through devectorization of the ith channel segment. n_{c} is the number of channels and n is the number of null-subspace bases. FIG. 1B shows PRUNO reconstruction being performed. Each null-subspace basis vⱼ in V_{⊥} is segmented and devectorized into 2D null-subspace convolution kernels fᵢⱼ^{null} forming the k-space nulling system matrix F. The missing k-space can be estimated by solving the nulling system equation F^{H}d=0. The nulling system is essentially composed of multiple 2D nulling convolutions and summations within multi-channel k-space. Missing k-space data can be reconstructed by solving this nulling system across the whole k-space with an iterative conjugate-gradient algorithm. In GRAPPA, as the acceleration factor increases, the correlation between the target samples and the fitting samples becomes weaker, thus requiring larger kernels to fit more samples. In contrast, the nulling system in PRUNO always continuously applies the local convolutions at all k-space locations regardless of the reduction factor [16]. With iterative reconstruction, all missing data will eventually be fitted by using all available k-space samples, during which the nulling kernel yields better fitting accuracy because of the larger number of fitted samples and better locality [16]. However, the iteration process in PRUNO reconstruction is computationally demanding and PRUNO does not offer the flexibility of incorporating image priors as in image- and hybrid-domain methods [21].

ESPIRIT extends the subspace concept in PRUNO further and provides a more computationally efficient hybrid-domain approach in which an extended SENSE based reconstruction can be performed [21]. As shown in FIG. 1C, the signal-subspace bases are extracted from the calibration matrix to form signal-subspace based shift-invariant convolutional kernels, which differ from the null-subspace based nulling kernels in PRUNO. FIG. 1C shows ESPIRIT reconstruction. fᵢⱼ^{sig} is obtained from the signal-subspace basis in V_{∥} and is transformed into an image-domain map sᵢⱼ^{sig}, which can form a large 2D overdetermined signal system matrix S^{sig}. Pixel-wise eigen-decomposition is then performed on the S^{sig} to calculate eigenvector maps (unmasked ESPIRIT maps) and eigenvalues. Only a single set of eigenvector maps is displayed. After a manual thresholding process, an eigenvalue mask is obtained to mask the eigenvector maps. With masked ESPIRIT maps E, an extended SENSE-based reconstruction can be applied. Each k-space kernel fᵢⱼ^{sig} is transformed into an image-domain map sᵢⱼ^{sig} through zero-padding denoted by Z and inverse fast Fourier transform (IFFT) denoted by [symbol] ⁻¹:

$$\begin{matrix}{s}_{ij}^{sig} = {- 1}^{} ( ( {f}_{ij}^{sig} ) ) , & i = 1 , … , {n}_{c} ; j = 1 , … , l\end{matrix} \qquad ( 2 )$$

where l is the number of signal-subspace bases. Then, an overdetermined signal system matrix S^{sig} can be formed in image domain:

$${{S}^{sig} ( {S}^{sig} )}^{H} m = m , where {S}^{sig} = [ \begin{matrix}{s}_{11}^{sig} & … & {s}_{1 n}^{sig} \\ ⋮ & ⋱ & ⋮ \\ {s}_{{n}_{c} 1}^{sig} & … & {s}_{{n}_{c} n}^{sig}\end{matrix} ] , m = [ \begin{matrix}{m}_{1} \\ ⋮ \\ {m}_{{n}_{c}}\end{matrix} ] . \qquad ( 3 )$$

Here m denotes multi-channel images. Masked ESPIRIT maps E that contain coil sensitivity information are then obtained by (i) performing pixel-wise eigen-decomposition on the system matrix to utilize its linear relationship to the coil sensitivities and (ii) masking the eigenvector maps using a manually chosen eigenvalue threshold to exclude the image background region so to minimize noise propagation during image reconstruction [21]. With the masked ESPIRIT maps E, SENSE based reconstruction can be performed to reconstruct the target image by using such estimated coil sensitivity information in E:

$${m}_{a} = {- 1}^{} ( {Em}_{0} ) \qquad ( 4 )$$

Here m₀ is the underlying target image and mₐ are the aliased multi-channel images reconstructed from undersampled k-space data. [symbol] is the fast Fourier transform (FFT) and [symbol] an operator that undersamples k-space. The multi-channel images m can then be written as:

$$m = E {m}_{0} \qquad ( 5 )$$

Although ESPIRIT extends the subspace concept in PRUNO while preserving the image-domain reconstruction flexibility, it requires the manual eigenvalue thresholding for masking coil sensitivity information, which is a cumbersome procedure in practice because such thresholding is image-content dependent. Further, ESPIRIT reconstruction quality can be sensitive to the arbitrary subspace division during the signal-subspace extraction process.

### SUMMARY OF THE INVENTION

According to the present invention the concepts of null-subspace PRUNO and hybrid-domain ESPIRIT are combined to provide a more robust reconstruction method for MRI images that extracts null-subspace bases of the calibration matrix from k-space coil calibration data to calculate image-domain spatial null maps (SNMs). The subsequent reconstruction of multi-channel images relies on solving an image-domain nulling system formed by SNMs that contain both coil sensitivity and finite image support information, thus circumventing the masking-related procedure. The method of the present invention was evaluated with multi-channel 2D brain and knee data, and compared to ESPIRIT.

Compared to the hybrid-domain reconstruction method of the present invention, the existing PRUNO method is a pure k-space reconstruction method that solves a nulling equation in the k-space domain. This means it cannot offer the flexibility of incorporating image priors such as image sparsity to further reduce noise amplification as hybrid-domain reconstruction methods. Besides, the present invention is computationally efficient since it directly calculates image-domain spatial nulling maps for sequential reconstruction, while k-space PRUNO needs many interactions for convergency and is computationally prohibitive in practice.

The hybrid-domain method of the present invention produces quality reconstruction highly comparable to ESPIRIT with optimal manual masking. It involved no masking-related manual procedure and is tolerant of the actual division of null- and signal-subspace. Spatial regularization can also be readily incorporated to reduce noise amplification as in ESPIRIT.

The existing ESPIRIT method performs eigenvalue decomposition on signal-subspace bases to calculate ESPIRIT maps and reconstruct images based on an extended SENSE algorithm. The main difference between ESPIRIT and our invention regarding the method part is that we utilize null-subspace bases and directly derive the proposed conceptually new spatial nulling maps (SNMs) using our invented algorithm. One of the biggest limitations of ESPIRIT is that it requires manually thresholding eigenvalues to mask the eigenvector maps to spatially define the image background region in order to minimize the noise propagation during image reconstruction. This procedure can be burdensome in practice since the optimal threshold is image-content dependent and often involves a trial-and-error selection. Using these spatial nulling maps, the proposed method eliminates the need for coil sensitivity masking and is relatively insensitive to the subspace division, thus offering a robust parallel imaging reconstruction procedure in practice.

In effect, the present invention proposes an algorithm to calculate the spatial nulling maps for more efficient and robust reconstruction, where the algorithm framework, and also the its generated maps are all newly developed. The result is an efficient hybrid-domain reconstruction method using multi-channel SNMs that are calculated from coil calibration data. Thus, the invention eliminates the need for coil sensitivity masking and is relatively insensitive to subspace separation, which presents a robust parallel imaging reconstruction procedure in practice.

### BRIEF DESCRIPTION OF THE DRAWINGS

The foregoing and other objects and advantages of the present invention will become more apparent when considered in connection with the following detailed description and appended drawings in which like designations denote like elements in the various views, and wherein:

FIG. 1A is a diagram of signal and null-subspace separation, FIG. 1B is a diagram of prior art PRUNO reconstruction, FIG. 1C is a diagram of prior art ESPIRIT reconstruction and

FIG. 1D is a diagram of reconstruction using spatial nulling maps (SNMs) according to the present invention;

FIG. 2 illustrates SNMs from one 6-channel T1W GRE dataset;

FIG. 3 shows reconstructed image results of the 6-channel TIW GRE data from two subjects with different head sizes;

FIG. 4 is a comparison of images from the present invention and images from the ESPIRIT reconstruction with different eigenvalue masking thresholds;

FIG. 5 shows reconstruction results of the present invention and ESPIRIT for 6-channel PDW knee data;

FIG. 6. shows reconstruction results of the present invention and ESPIRIT for 6-channel SSFP cardiac data;

FIG. 7 shows reconstruction results of the present invention versus ESPIRIT results using a manually optimized eigenvalue threshold with different σ²_{cut-off} for subspace division;

FIG. 8 shows reconstruction results of the present invention with different L₁-norm sparsifying regularization weights;

FIG. 9A shows reconstruction results of the present invention versus ESPIRIT results using a manually optimized eigenvalue threshold with extremely small σ²_{cut-off} for subspace division and FIG. 9B shows the same reconstructions results with extremely large σ²_{cut-off} for subspace division;

FIG. 10A shows graphs of normalized root mean square error (NRMSE) and structural similarity index measure (SSIM) values corresponding to the brain image reconstruction results from two subjects shown in FIG. 4 and knee image results from FIG. 5 with different eigenvalue thresholds and FIG. 10B shows NRMSE and SSIM values with different σ²_{cut-off} for subspace division, corresponding to the brain image reconstruction results from two subjects shown in FIG. 6;

FIG. 11 shows reconstruction results from two-fold under-sampled data with a field-of-view (FOV) smaller than the object;

FIG. 12 shows reconstruction results of the 6-channel TIW GRE brain data with only 16 central consecutive k-space lines preserved; and

FIG. 13 is a flowchart of a process for reconstructing non-Cartesian data.

### DETAILED DESCRIPTION OF THE INVENTION

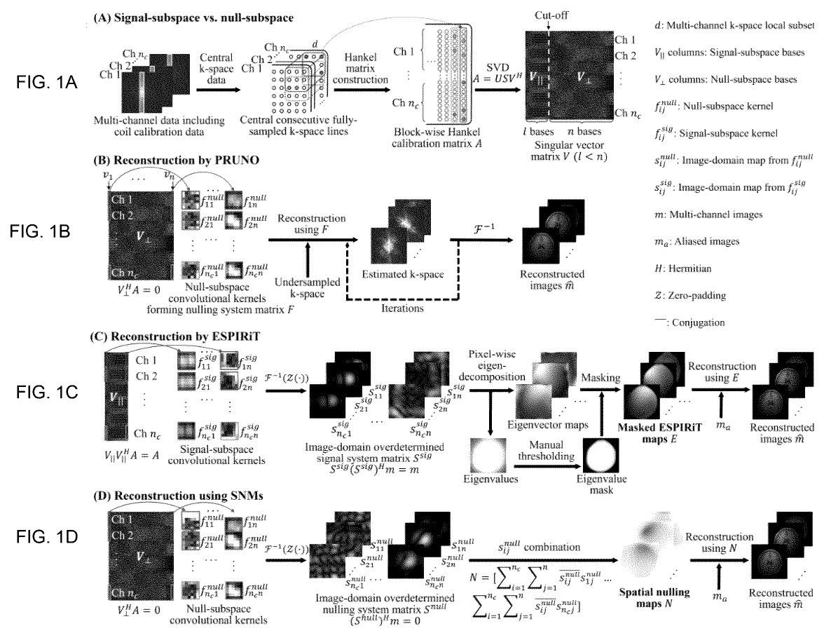

In the present invention the concepts of the null-subspace reconstruction in PRUNO and the hybrid-domain reconstruction in ESPIRIT are integrated to provide a new and more robust parallel imaging (PI) reconstruction method. The method of the invention extracts null-subspace bases of k-space calibration matrix and directly derives a set of image-domain spatial nulling maps from these null-subspace bases. FIG. 1D shows reconstruction using spatial null maps (SNMs). The null-subspace basis vⱼ in V_{⊥} is used to obtain fᵢⱼ^{null} and is successively transformed into sᵢⱼ^{null} forming a large overdetermined nulling system matrix S^{null}. Instead of solving the overdetermined system, all sᵢⱼ^{hull} are combined to construct multi-channel SNMs denoted by N. Images can be then reconstructed by solving the system established using N and multi-channel images m. The spatial nulling maps explicitly represent both coil sensitivity and finite image support information and form an image-domain nulling system for subsequent image reconstruction. The specific reconstruction steps are described below.

First, the central consecutive fully-sampled k-space lines within the multi-channel k-space data are used to construct a block-wise Hankel calibration matrix A, in which the column entries (i.e., vectorized k-space blocks) exhibit strong linear dependencies [9, 16, 17, 21] (FIG. 1A). By performing the singular value decomposition (SVD), the singular vector matrix V with signal/null-subspace bases of A can be obtained:

$$A = {USV}^{H} \qquad ( 6 )$$

where V^{H} represents the Hermitian matrix of V. By setting a cut-off, the signal-subspace spanned by V_{∥} and null-subspace spanned by V_{⊥} are separated. Assuming that the two subspaces are ideally separated, two constraints are satisfied:

$${V}_{\vert \vert} {V}_{\vert \vert}^{H} A = A and \qquad ( 7 )$$

$${V}_{⊥}^{H} A = 0. \qquad ( 8 )$$

With extracted V_{⊥}, the segment corresponding to the ith channel of each null-subspace basis vⱼ is transformed into a 2D null-subspace convolution kernel fᵢⱼ^{null} through devectorization. According to Equation (8), a convolutional nulling relation between fᵢⱼ^{null} and multi-channel k-space data can be established:

$$\begin{matrix}{\sum }_{i = 1}^{{n}_{c}} {f}_{ij}^{null} * {k}_{i} = 0 , & j = 1 , … , n\end{matrix} \qquad ( 9 )$$

where kᵢ denotes the k-space data from the ith channel. In contrast to PRUNO, each k-space kernel fᵢⱼ^{null} is transformed into an image-domain map sᵢⱼ^{null} through zero-padding and IFFT:

$$\begin{matrix}{s}_{ij}^{null} = {- 1}^{} ( ( {f}_{ij}^{null} ) ) , & i = 1 , … , {n}_{c} ; j = 1 , … , n .\end{matrix} \qquad ( 10 )$$

Using sᵢⱼ^{null}, an image-domain overdetermined nulling system can be formed:

$$\begin{matrix}{( {S}^{null} )}^{H} m = 0 , & where {S}^{null} = [ \begin{matrix}{s}_{11}^{null} & … & {s}_{1 n}^{null} \\ ⋮ & ⋱ & ⋮ \\ {s}_{{n}_{c} 1}^{null} & … & {s}_{{n}_{c} n}^{null}\end{matrix} ] .\end{matrix} \qquad ( 11 )$$

Here S^{null} is a large 2D overdetermined nulling system matrix. Instead of solving the overdetermined system in Equation (11) for image reconstruction, multiple sᵢⱼ^{null} are combined to construct multi-channel spatial nulling maps N:

$$N = [ \text{} {\sum }_{i = 1}^{{n}_{c}} {\sum }_{j = 1}^{n} \overline{{s}_{ı}^{null}} \text{} {s}_{1 j}^{null} \text{} {\sum }_{i = 1}^{{n}_{c}} {\sum }_{j = 1}^{n} \overline{{s}_{ı}^{null}} \text{} {s}_{2 j}^{null} \text{} … {\sum }_{i = 1}^{{n}_{c}} {\sum }_{j = 1}^{n} \overline{{s}_{ı}^{null}} {s}_{{n}_{c} j}^{null} ] , \qquad ( 12 )$$

where s̅ᵢ̅ⱼ̅^̅{̅h̅u̅l̅l̅}̅ denotes the conjugation of sᵢⱼ^{null}. With N, an image-domain nulling system can be built:

$$N m = 0 . \qquad ( 13 )$$

Here m can be further represented as m=mₐ+mₘ, where the mₘ denotes the multi-channel images corresponding to the underlying missing k-space data. Therefore, the image-domain nulling system in Equation (13) becomes:

$$N ( {m}_{a} + {m}_{m} ) = 0 . \qquad ( 14 )$$

The multi-channel images m (i.e. mₐ+mₘ) can then be reconstructed by solving this nulling system. Specifically, with spatial nulling maps N estimated from the central k-space lines, a least-square solution of mₘ in Equation (14) can be calculated [29]:

$${\hat{m}}_{m} = arg {min}_{{m}_{m}} {‖ N ( {m}_{a} + {m}_{m} ) ‖}_{2}^{2} + {‖ 𝒫 ℱ {m}_{m} ‖}_{2}^{2} . \qquad ( 15 )$$

Here ∥ [symbol] [symbol] mₘ∥₂² is the data consistency term. Further, as in SENSE and ESPIRIT, the reconstruction can readily incorporate regularization terms Ψ to further reduce image noise by forming:

$${\hat{m}}_{m} = arg {min}_{{m}_{m}} {‖ N ( {m}_{a} + {m}_{m} ) ‖}_{2}^{2} + {‖ 𝒫 ℱ {m}_{m} ‖}_{2}^{2} + αΨ ( {m}_{a} + {m}_{m} ) \qquad ( 16 )$$

where α is the regularization weight.

Both the method of the present invention and ESPIRIT extend the subspace notion of PRUNO and provide computationally more efficient and flexible hybrid-domain reconstruction. However, unlike ESPIRIT, spatial nulling maps in the method of the present invention contain both coil sensitivity and finite image support information.

The subspace bases that satisfy the constraints in Equations (7) and (8) essentially represent the underlying low-frequency modulations in MR data, which can be indicated as k-space convolutions with limited kernel size or image-domain multiplications by smooth varying maps. Two dominating low-frequency modulations for multi-channel MR images are coil sensitivity and finite image support because of the nature of their slow spatial variation. Note that such finite image support information is related to the finite boundary of the object within the field-of-view (FOV) [30], and it has been used in the past for parallel imaging reconstruction [31-33].

In the presence of finite image support (i.e., when the imaging FOV is larger than the object), a nulling relationship inherently exists between the finite image support p and MR images:

$$( 1 - p ) m = 0 . \qquad ( 17 )$$

Considering Equation (11), the complement of the finite image support (i.e., 1−p) here is indeed embedded within the null-subspace S^{null} of m in the image domain. Note that, in k-space, such finite image support information, i.e., [symbol] (1−p), is represented within the null-subspace convolutional kernels described in Equation (9). Thus the spatial nulling maps N computed as in Equation (12) contain both coil sensitivity information and finite image support information. Therefore, the method of the present invention enables image reconstruction that involves no explicit masking-related procedure (see FIG. 1C vs. FIG. 1D).

The method of the present invention is relatively tolerant of inaccurate subspace separation. In ESPIRIT, the subspace separation determines the number of signal-subspace bases being extracted, which dominates the accuracy of S^{sig} and needs to be fine-tuned (FIG. 1C). Therefore, when performing pixel-wise eigen-decomposition on S^{sig}, the coil sensitivity information is affected by the subspace separation. In the method of the present invention, the null subspace separation determines the number of null-subspace bases and hence influences the accuracy of spatial nulling maps. However, for multi-channel MR data, the number of signal-subspace bases is much smaller than the number of null-subspace bases (i.e., l<n) because of the redundancy and linear dependency within MR data. Therefore, when the subspace separation is inaccurate, i.e., extracting relatively excessive or insufficient numbers of signal/null-subspace bases, the null-subspace spanned by n bases is overall less affected than the signal-subspace spanned by l bases.

Publicly available human MR datasets were used to evaluate the method of the present invention. They included 3T T1-weighted (T1W) GRE brain data from Calgary-Campinas Public Brain MR Database [34], 1.5T proton density-weighted (PDW) FSE knee data from the Fast MRI database and 1.5T SSFP cardiac data from the OCMR database [36]. TIW brain data were acquired using a 12-channel coil and 3D GRE with TR/TE/TI=6.3/2.6/400 ms, FOV=256×218×170 mm³, and matrix size=256×218×170. They were retrospectively transformed into 256×218 2D data. PDW knee data were acquired using a 15-channel coil and 2D FSE with TR/TE=2200/27 ms, FOV=160×160 mm², and matrix size=320×320. SSFP cardiac data were acquired using a 28-channel coil with TR/TE/TI=28.5/1.43/300 ms, FOV=720×270 mm³, and matrix size=320×120. All MR data were retrospectively under-sampled in a uniform manner at R=2, 3, and 4 while preserving 24 (out of 218 lines), 36 (out of 320 lines), or 24 (out of 120 lines) central consecutive k-space lines for the brain, knee, and cardiac data, respectively. The data used in the implementation of the present invention were compressed to 6-channel data by coil compression [37,38].

The method of the present invention was evaluated and compared to the ESPIRIT. For ESPIRIT reconstruction, the eigenvector maps that contain coil sensitivity information were termed ESPIRIT maps. Both spatial nulling maps and ESPIRIT maps were estimated from the central consecutive k-space lines. An L₁-norm wavelet sparsity regularization with the regularization weight λ=0.002 was also applied to both the method of the present invention and ESPIRIT. The kernel size for both the method of the present invention and ESPIRIT was set to 6×6. Two sets of eigenvector maps were applied in ESPIRIT for the extended SENSE based reconstruction. For both ESPIRIT and the method of the present invention, the signal/null-subspace cut-off was set according to a manually determined σ²_{cut-off} relative to the maximum singular value as in previous ESPIRIT studies [21].

In an ESPIRIT reconstruction, the eigenvalue threshold for the masking coil sensitivity information was manually optimized. They were 0.996, 0.96, and 0.95 for two brain datasets (with two very different head sizes) and one knee dataset, respectively. The performance with suboptimal threshold selection in ESPIRIT was also evaluated by deliberately setting the threshold smaller or larger than the optimal value.

The final reconstructed images were generated by combining all coil images using the square root sum-of-squares method. In addition to comparing the images reconstructed from the method of the present invention and ESPIRIT, the residual error maps were calculated as the square root sum-of-squares of the coil-by-coil difference between the reconstructed images and reference images reconstructed from the fully sampled data. Normalized root mean squared error (NRMSE) and structural similarity index measure (SSIM) were calculated within the brain or knee region. The L₁-norm of sparsifying wavelet transform with different regularization weights (λ=0.001, 0.002, 0.003, and 0.004) was also applied for evaluation. In the implementation of the present invention, the objective function minimized the joint-sparsity [18,40-42] of multiple channels, which differed from the channel-combined image sparsity in the ESPIRIT [21].

The method of the present invention was further evaluated using one 8-channel dataset with a FOV of 200 mm×150 mm that was smaller than the head size. Then 24 central consecutive k-space lines out of 256 lines were preserved. The method of the present invention and its evaluation were implemented using MATLAB R2020b (Math Works, Natick, MA). All codes and test data can be obtained online (https://github.com/jiahao919/SNMs) or from the authors upon request.

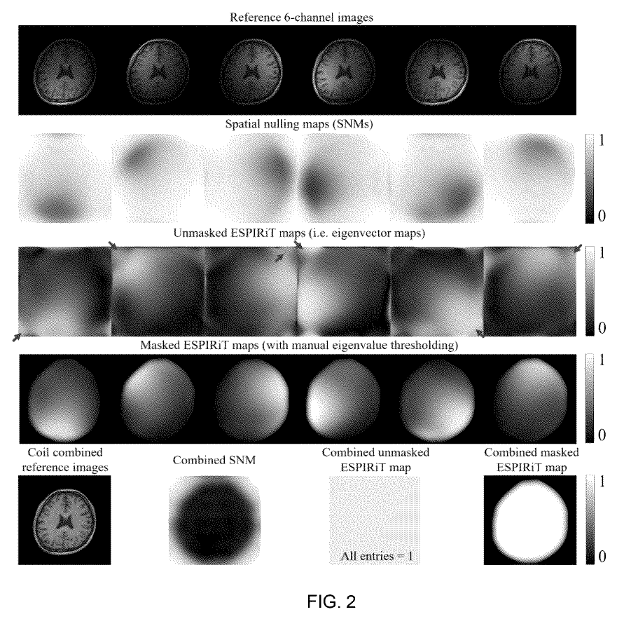

FIG. 2 displays the spatial nulling maps (SNMs) from one 6-channel TIW brain dataset, together with the corresponding unmasked ESPIRIT maps as well as masked ESPIRIT maps through manually optimized eigenvalue thresholding. It is evident that unmasked ESPIRIT maps and SNMs both provided coil sensitivity information. However, SNMs provided additional information on the finite image support. Note that the sum-of-squares combination of SNMs clearly delineated the image support boundary, indicating that finite image support information was indeed embedded in SNMs. In contrast, the combination of unmasked ESPIRIT maps did not contain such information. In FIG. 2, for the method of present invention, the complement of finite image support can be demonstrated by combined SNM. In unmasked ESPIRIT maps, the image object region could not be distinguished from the background (as shown by arrows) and the combined unmasked ESPIRIT map is an identity or uniform map as expected. Only in masked ESPIRIT maps as well as their combined map, was the finite support of the object delineated. Note that the matrix size for SNMs and ESPIRIT maps was 256×218. They were computed from 24 central consecutive k-space lines.

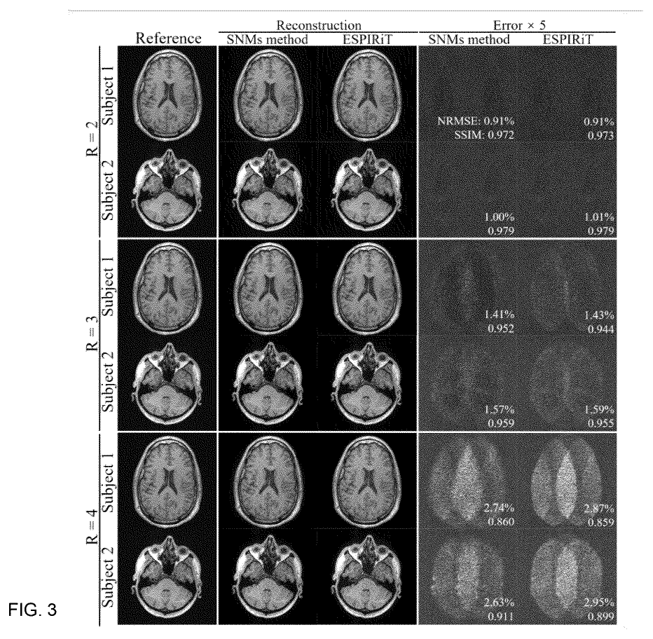

FIG. 3 compares the reconstruction using SNMs and manually optimized ESPIRIT at various acceleration factors (R=2, 3, and 4). The method of the present invention provided reconstruction results with noise level and residual artifacts that were highly comparable to ESPIRIT results at low acceleration factors (R=2 and 3). As the acceleration factor increased (R=4), reconstruction using SNMs slightly outperformed the ESPIRIT in terms of noise and artifact levels within the brain region as indicated by NRMSE and SSIM values. Note that ESPIRIT reconstruction was conducted by carefully optimizing the eigenvalue threshold and subspace separation to ensure its optimal reconstruction performance. In contrast, the method of the present invention required no masking-related procedure because the finite image support information was already embedded in the SNMs. In particular, FIG. 3 shows the reconstruction results of the 6-channel TIW GRE data from two subjects with different head sizes (i.e., varying finite image support) at R=2, 3, and 4. ESPIRIT reconstruction was manually optimized for the eigenvalue threshold selection and subspace separation to ensure its best performance. The proposed SNMs method provided reconstruction results that were highly comparable to ESPIRIT at low acceleration factors (R=2 and 3). At R=4, reconstruction using SNMs outperformed ESPIRIT visually, which was also evident from the normalized root mean squared error (NRMSE) in percentage and structural similarity index measure (SSIM) values measured within the brain region. Error maps are displayed with enhanced brightness (×5).

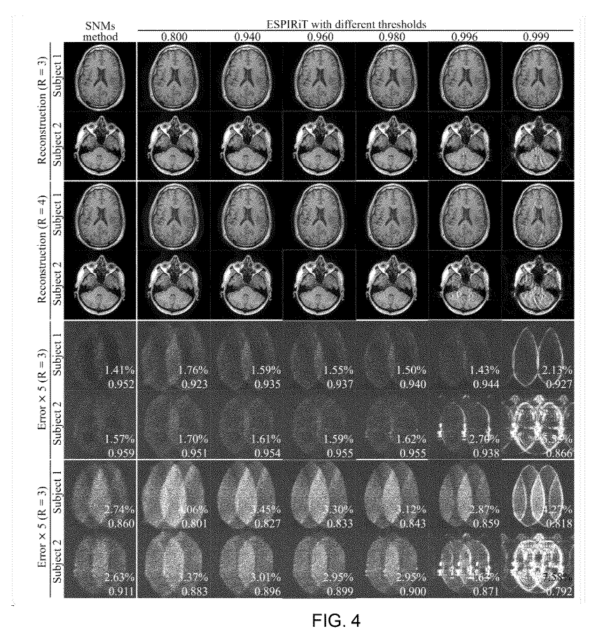

FIG. 4 shows the reconstruction results of the method of the present invention vs. the ESPIRIT reconstruction results that utilized different eigenvalue thresholds (0.8˜0.999) for masking coil sensitivity information. In FIG. 4 the different eigenvalue masking thresholds are with R=3 and 4. The results with manually optimized thresholds are shown with boxes. Either larger or smaller threshold values strongly degraded ESPIRIT reconstruction performance. In contrast, the SNMs method of the present invention was free from such phenomenon, yet its performance was always highly comparable to the best ESPIRIT results. Such threshold selection clearly affected the ESPIRIT reconstruction performance in terms of noise or artifact levels. When the threshold was smaller than the optimal one, a larger eigenvalue mask occurred. Consequently, the reconstructed images exhibited significant noise increase in both brain region and background as expected. Conversely, when the threshold was larger than the optimal one, the mask size decreased, leading to severe artifacts and noise. Note that the optimal threshold was highly dependent of the image content, mainly object size and shape. Thus, it must be manually determined in a trial-and-error manner by judging the reconstruction quality. In contrast, the reconstruction using SNMs completely circumvented such a masking-related procedure, demonstrating a more robust reconstruction than ESPIRIT.

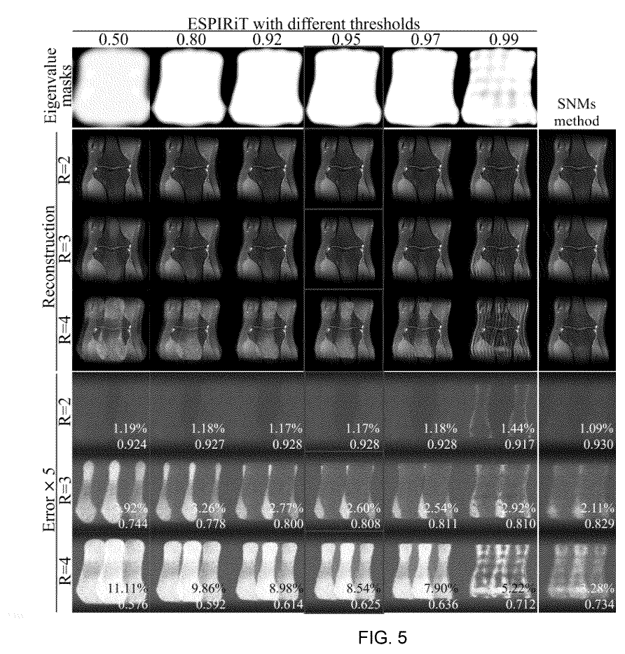

The reconstruction results of 6-channel knee data at R=2, 3, and 4 using the method of the present invention and ESPIRIT with different thresholds are shown in FIG. 5. The thresholds in ESPIRIT reconstruction ranged from 0.5 to 0.99. Eigenvalue masks in ESPIRIT were also displayed to show the influences of different thresholds. The method of the invention led to less noise amplification and/or fewer residual artifacts than ESPIRIT in terms of NRSME and SSIM values, especially at high acceleration factors. With the threshold larger or smaller than the optimal value, ESPIRIT reconstruction exhibited severe artifacts and noise, especially at R=3 and 4.

Threshold values smaller than the optimal value yielded larger masks, causing more noise amplification. Larger threshold values led to smaller masks and significantly increased the number of artifacts. Meanwhile, the method of the present invention achieved overall low noise and artifact level when compared with ESPIRIT, especially at high acceleration.

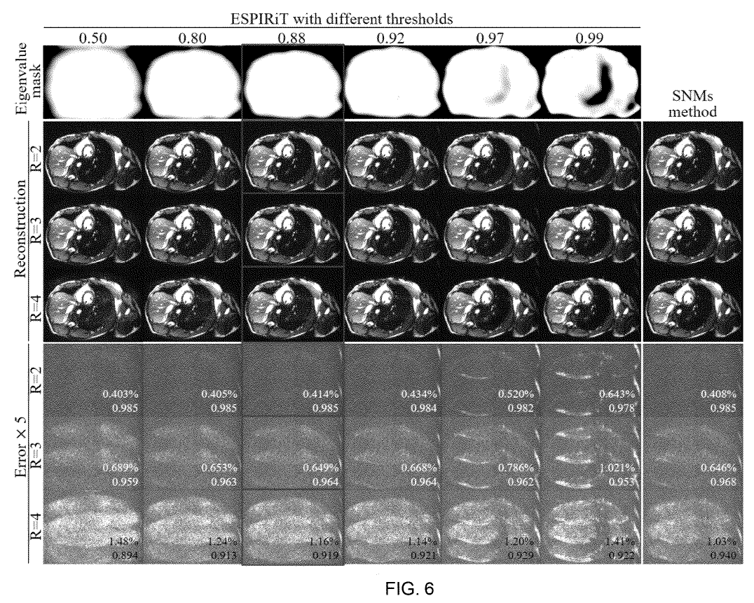

FIG. 6 shows the reconstruction results of ESPIRIT for 6-channel SSFP cardiac data at R=2, 3, and 4 and the method of the present invention. ESPIRIT was used with different thresholds. Compared to the head and knee datasets, large signal voids and susceptibility artifacts were present within the abdominal region. As shown in the results, ESPIRIT reconstruction performance could be affected by threshold selection. When using a threshold larger than the optimal, the low intensity region and the edge region were masked out, causing severe artifacts and/or noise. Large noise amplification was seen when using a threshold smaller than the optimal one. In contrast, the present method consistently achieved quality reconstruction results, that were comparable to the optimized ESPIRIT results at R=2 and 3, and better than the optimized ESPIRIT result at R=4.

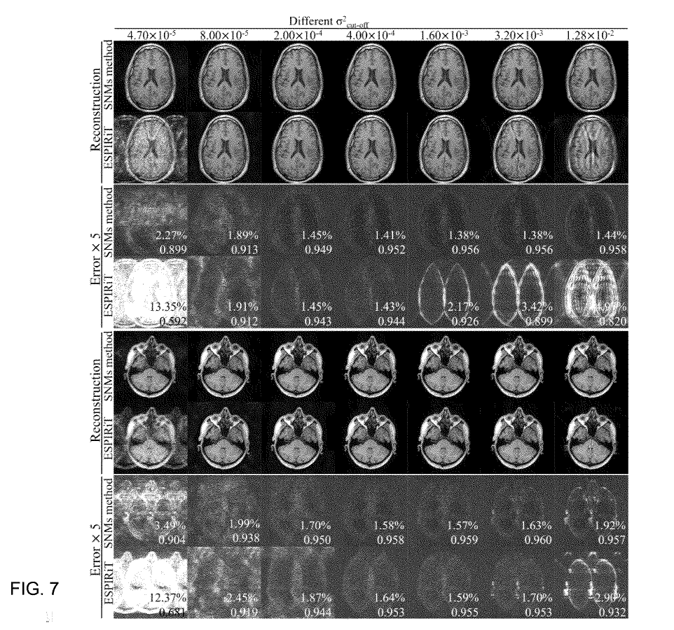

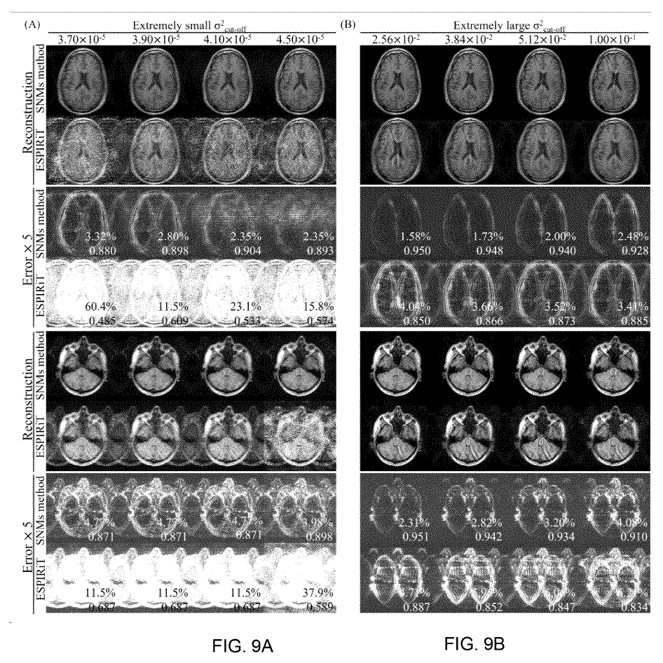

To examine the effect of different subspace divisions, FIG. 7 compares the reconstruction results of the method of the present invention and the ESPIRIT results (using a manually optimized eigenvalue threshold) with varying σ²_{cut-off} for one brain dataset at R=3 for two 6-channel brain datasets. The number of bases in the signal-subspace l and null-subspace n corresponding to different σ²_{cut-off} is given in TABLE 1. Both the method of the invention and the ESPIRIT performance degraded at suboptimal σ²_{cut-off}. However, the method of the invention was overall less sensitive to the σ²_{cut-off} selection. Specifically, the method of the present invention only showed a slightly increased noise level for extremely small σ²_{cut-off} or residual artifacts for extremely large σ²_{cut-off} and it could tolerate approximately 30% deviation from optimal σ²_{cut-off}. In contrast, ESPIRIT with suboptimal σ²_{cut-off} exhibited severe noise (for smaller σ²_{cut-off}) or residual artifacts (for large σ²_{cut-off}), significantly compromising the final image quality. Results with a wider range of σ²_{cut-off} are shown in FIG. 9. In particular, FIG. 9A shows the results for extremely small σ²_{cut-off} and FIG. 9B shows the results for extremely large σ²_{cut-off}. The corresponding number of bases is shown in TABLE 2.

TABLE 1
The number of signal- and null-subspace bases corresponding to different σ²_{cut-off}

| σ²_{cut-off} | 4.70 × 10⁻⁵ | 4.80 × 10⁻⁵ | 8.00 × 10⁻⁵ | 2.00 × 10⁻⁴ | 4.00 × 10⁻⁴ | 1.60 × 10⁻³ | 3.20 × 10⁻³ | 1.28 × 10⁻² |
|---|---|---|---|---|---|---|---|---|
| l | 211 | 210 | 175 | 103 | 66 | 50 | 47 | 38 |
| n | 5 | 6 | 41 | 113 | 150 | 166 | 169 | 178 |

TABLE 2
The number of signal- and null-subspace bases for a wider range of σ²_{cut-off} corresponding to FIG. 9

| σ²_{cut-off} | 3.70 × 10⁻⁵ | 3.9 × 10⁻⁵ | 4.1 × 10⁻⁵ | 4.5 × 10⁻⁵ | 2.56 × 10⁻² | 3.84 × 10⁻² | 5.12 × 10⁻² | 1.00 × 10⁻¹ |
|---|---|---|---|---|---|---|---|---|
| l | 215 | 214 | 213 | 212 | 35 | 32 | 29 | 26 |
| n | 1 | 2 | 3 | 4 | 181 | 184 | 187 | 190 |

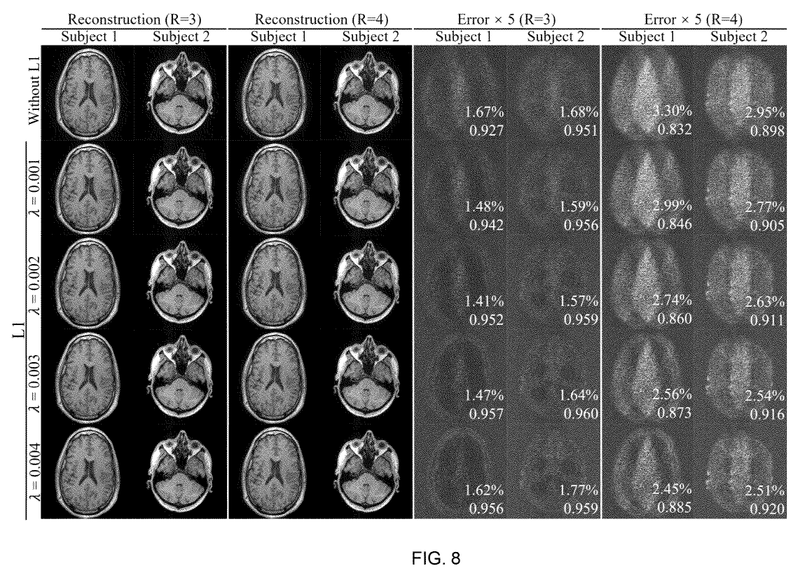

To demonstrate the incorporation of regularization into the method of the present invention, FIG. 8 displays reconstruction results with different L₁-norm sparsifying regularization weights at acceleration factor R=3 and 4 and with regularizations weights λ=0.001, 0.002, and 0.003. These results demonstrate the SNMs method as a hybrid-domain method that is flexible and can incorporate L₁-norm regularization to reduce the noise at the expense of a certain degree of image blurring. With the regularization, the noise is suppressed in the reconstructed images as expected.

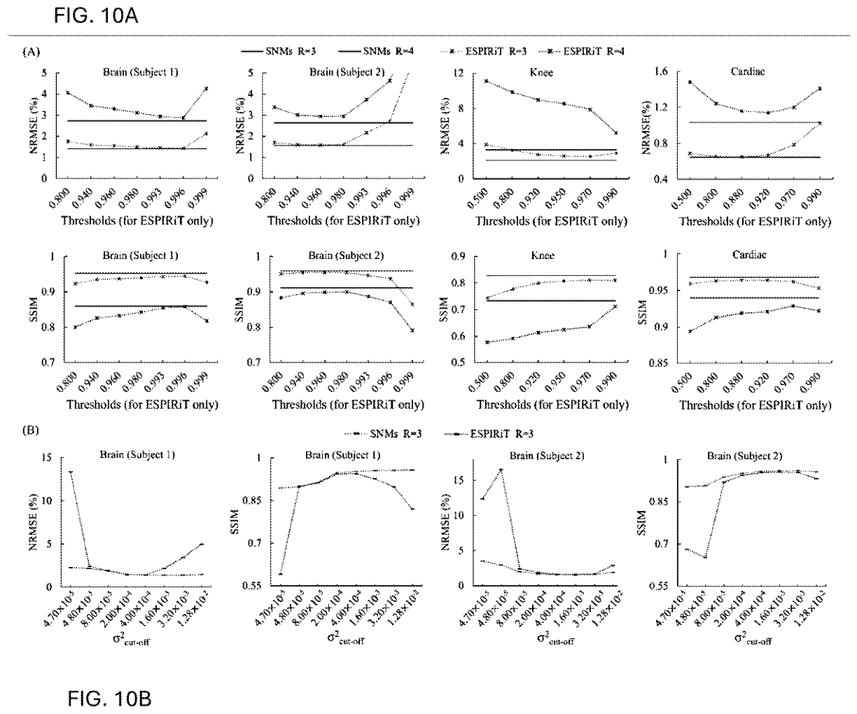

FIG. 10 plots the NRMSE and SSIM values that corresponded to the results shown in FIGS. 4 to 6, i.e., the brain image reconstruction results from two subjects shown in FIG. 4, the knee image results from FIG. 5 with different eigenvalue thresholds, and the NRMSE and SSIM values with different σ²_{cut-off} for subspace division, corresponding to the brain image reconstruction results from two subjects shown in FIG. 6. They again indicate that optimal ESPIRIT reconstruction required the optimization of the eigenvalue threshold values for masking, whereas the present invention involved no such optimization (FIG. 10A). In general, the method of the present invention yielded better performance than ESPIRIT in terms of NRMSE and SSIM values within the object regions, especially at high acceleration. The reconstruction improvement of the present invention over ESPIRIT became more apparent for knee results. As shown in FIG. 10B, the method of the present invention achieved overall better reconstruction than ESPIRIT. More importantly, the method of the present invention was more tolerant of inaccurate σ²_{cut-off} selection for subspace separation as evident from the NRMSE and SSIM values.

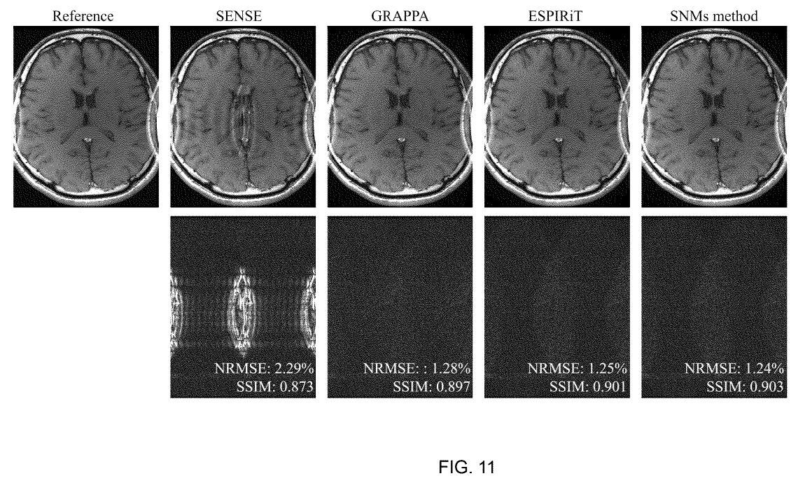

Reconstruction from two-fold under-sampled data with a FOV smaller than the object is shown in FIG. 11. The dataset was from ESPIRIT open sources [21], which were acquired using a 2D spin-echo sequence (TR/TE=550/14 ms, FA=90°, BW=19 kHz, matrix size=320×256, slices=6, slice thickness=3 mm). Then 24 central consecutive k-space lines were preserved out of 256 lines. The SENSE method using a single set of smooth coil sensitivity maps could not recover the correct coil sensitivity information. Such a SENSE reconstructed image suffered from a severe artifact. GRAPPA, ESPIRIT (with 2 sets of ESPIRIT maps) and the SNMs method were able to reconstruct the data. The SNM method of the present invention provided quality results comparable to ESPIRIT using two sets of maps, in terms of the noise and artifact levels as indicated by NRMSE and SSIM values.

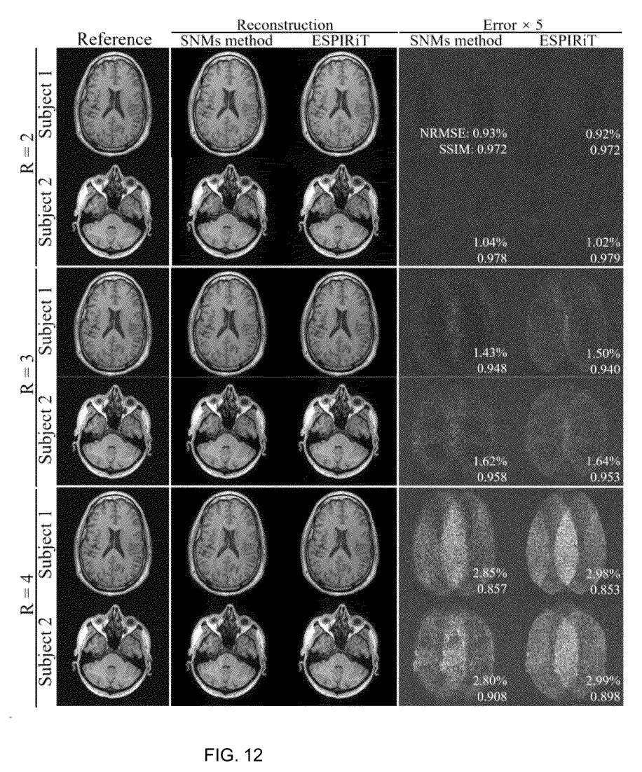

In addition to the reconstruction using 24 central consecutive k-space lines (FIG. 3), the method of the present invention was further evaluated by determining the results of the 6-channel TIW GRE brain data with the number of central consecutive k-space lines reduced to 16 (FIG. 12). Again, the proposed SNMs method showed its robustness and provided reconstruction results that were highly comparable to ESPIRIT at low acceleration factors (R=2 and 3) and slightly better than ESPIRIT at high acceleration factor (R=4).

The present invention is a novel hybrid-domain reconstruction method. It extracts null-subspace bases of a calibration matrix constructed from coil calibration data (i.e., autocalibrating or additional calibration scan data) and calculates image-domain spatial nulling maps (SNMs) that contain both coil sensitivity and finite image support information. This null-subspace based method completely eliminates the need for any masking-related procedure. It is also relatively insensitive to subspace cut-off selection, offering more robust reconstruction than the signal-subspace based ESPIRIT method.

The subspace bases calculated through singular value decomposition (SVD) of the constructed block-wise Hankel matrix theoretically represents all of the underlying low-frequency modulations (k-space convolutions with a limited kernel size or image-domain multiplications by smooth maps) in MR data. Coil sensitivity and finite image support are two dominant low-frequency modulations within the MR data [43]. The coil sensitivity information is successfully estimated in ESPIRIT. In the method of the present invention, the finite image support information is mathematically incorporated by extracting null-subspace bases and combining their image-domain transformations as in Equation (12). This finite image support utilization is based on an analysis that the multiplication between the complement of the finite image support and MR images formulates an image-domain nulling equation as described by Equation (17), indicating the existence of the finite image support information within the null-subspace. The finite support information embedded in SNMs is also evidence from the experimental results shown in FIG. 2, which illustrates that the combined SNM delineated the complement of the finite image support of the object to be imaged (i.e., 1−p). Thus, the null-subspace based approach of the present invention and resulting SNMs enable a masking-free hybrid-domain reconstruction method as demonstrated in FIGS. 3-5.

When the imaging FOV is smaller than the object, the signal cannot be represented correctly using a single set of sensitivity maps on the restricted FOV. Thus ESPIRIT utilizes two sets of ESPIRIT maps to represent the fold-over images and their corresponding sensitivity information. Transformed from multiple null-subspace kernels, the spatial nulling maps are capable of representing such fold-over sensitivity information and can be used to reconstruct the small FOV data. In such a case, the method of the present invention achieves quality reconstruction comparable to ESPIRIT (FIG. 11).

The signal- or null-subspace separation is required in both ESPIRIT and the method of the present invention. The subspace bases represent the low-frequency modulations within MR data. ESPIRIT obtains coil sensitivity information from signal-subspace bases while the method of the present invention obtains both coil sensitivity and finite image support information from null-subspace bases. In ESPIRIT, a precise subspace separation is required to ensure the extracted bases satisfy the signal-subspace constraint in Equation (7). If insufficient or excessive bases are extracted, the constraint formed by those bases will be inaccurate. This leads to an inaccurate estimation of coil sensitivity information, causing noise or residual artifacts in the reconstructed results (FIG. 6). In the method of the present invention, null-subspace bases satisfying the null-subspace constraint in Equation (8) need to be extracted. The excessively extracted bases beyond the null-subspace (i.e., including certain signal-subspace data) cannot satisfy the null-subspace constraint, which may cause incorrect sᵢⱼ^{null}. Similarly, insufficient null-subspace bases can generate insufficient sᵢⱼ^{null}. Both scenarios can lead to the inaccuracy of SNMs. However, the method of the present invention is less sensitive to such subspace separation compared with ESPIRIT, as demonstrated in FIG. 6 and FIG. 9. Such tolerance of inaccurate subspace separation primarily arises from the fact that the number of signal-subspace bases corresponding to dominant singular values is much smaller than the null-subspace bases due to the high redundancy and high linear dependency within MR data.

Another potential factor contributing to such relative insensitivity is that, compared with the method of the present invention that directly combines multiple sᵢⱼ^{null} to obtain SNMs, ESPIRIT requires one more eigen-decomposition step and introduces manual thresholding before the reconstruction. This procedural difference may cause stronger error propagation in the reconstruction when the subspace separation is inaccurate.

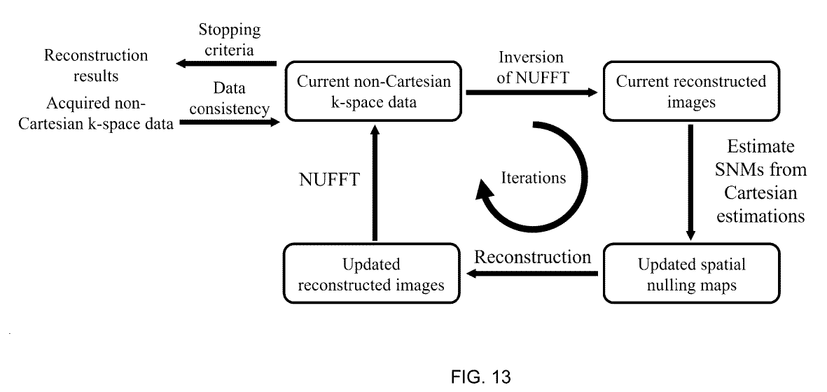

The SNMs method of the present invention can be extended from Cartesian to non-Cartesian imaging. For non-Cartesian imaging [44], a nonuniform fast Fourier transform (NUFFT) [45,46] can be used to establish the connection between the acquired non-Cartesian data and the estimated Cartesian data. Specifically, images can be calculated by inverse NUFFT and sequentially transformed into Cartesian estimations. Null-subspace kernels can then be constructed from the Cartesian estimations and transformed into spatial nulling maps. The images can be reconstructed by iteratively solving the nulling system equation, during which the spatial nulling maps are updated, and data consistency is enforced. A flowchart of the process for reconstructing non-Cartesian data is shown in FIG. 13. Nonuniform fast Fourier transform (NUFFT) establishes the connection between the acquired non-Cartesian data and estimated Cartesian data. The images are reconstructed by iteratively solving the nulling system equation, during which the spatial nulling maps are updated and data consistency is enforced.

In implementing the present invention a personal desktop computer with 4-core i5-6500 CPU was used. The reconstruction codes were written using MATLAB R2020b (Math Works, Natick, MA). The method of the present invention is computationally efficient. In particular, the calculation of 6-channel SNMs for a single 2D 256×218 slice at R=4 and the reconstruction took ˜2 and ˜6 seconds without and with L₁-norm sparsifying regularization, respectively. The computational times for the 2D single-slice reconstruction using the method of the present invention and ESPIRIT from the first subject in FIG. 3 are summarized in TABLE 3. The computational efficiency of the method of the present invention was similar to ESPIRIT, yet much higher than PRUNO, which requires hundreds of iterations to converge and each iteration can take about 2 seconds for a 2D 256×256 slice on 4-core CPU to converge (e.g., 8 minutes to reconstruct one slice at effective R=4 [16]).

TABLE 3
Computational time corresponding to the single-slice 2D
reconstruction from the first subject shown in FIG. 3

| | | R = 2 | R = 3 | R = 4 |
|---|---|---|---|---|
| No | SNMs | 0.5 s | 1.8 s | 2.5 s |
| regularization | ESPIRiT | 1.3 s | 4.6 s | 7.9 s |
| With | SNMs | 4.3 s | 5.5 s | 6.3 s |
| regularization | ESPIRiT | 3.0 s | 5.8 s | 9.7 s |

As another null-subspace method, PRUNO solves the inverse problem in the k-space and the method of the present invention converts the problem and solves it in the image domain. They are similar in general problem formulation, but the method of the present invention provides advantages in terms of computational efficiency and explicit usage of maps with coil sensitivity information.

The hybrid-domain SNMs method of the present invention is more computationally efficient than k-space PRUNO. When solving the inverse problem by least square minimization, the image domain minimization in the method of the present invention could have different converging behavior, e.g., converging speed and numerical stability during conjugate gradient descent, compared to the k-space PRUNO. This is evident from the fact that PRUNO reconstructs data very slowly and needs an extra step to perform GRAPPA as an initial guess for increasing convergence speed and/or more accurate estimates [16]. Even so, PRUNO still entails a long reconstruction time. Compared to PRUNO, the proposed SNM method is much faster and can reconstruct one slice within a few seconds (TABLE 3). More importantly, the SNM method does not require any initial guess, and still converges fast and robustly. Therefore, the method of the present invention is more efficient. Such features are important in practice. Furthermore, with the fast convergency, the method of the present invention can be extended to potentially real-time 3D or 4D dynamic imaging.

The method of the present invention derives image-domain spatial nulling maps with explicit coil sensitivity information. Such image-domain coil maps offer more choices in utilizing prior information related to coil sensitivity. For example, in recent studies [48,49], the coil sensitivity information could be directly estimated by a deep learning neural network. Prior knowledge such as subject-coil geometry information was incorporated. They offered parallel imaging approaches that required a few number of or no ACS lines. Such a strategy can also be combined with the proposed SNM method for more robust reconstruction, further demonstrating the flexibility of the proposed hybrid-domain method compared to k-space PRUNO.

The present invention provides a flexible and efficient hybrid-domain parallel imaging reconstruction method that extracts null-subspace bases of calibration matrix to calculate image-domain SNMs. Multi-channel images are reconstructed by solving a nulling system formed by SNMs that explicitly contain coil sensitivity and finite image support information. The proposed hybrid-domain method shows quality reconstruction that is highly comparable to ESPIRIT with optimal manual masking. More importantly, it eliminates the need for coil sensitivity masking and is relatively insensitive to subspace division, thus offering a robust parallel imaging reconstruction procedure in practice.

The above are only specific implementations of the invention and are not intended to limit the scope of protection of the invention. Any modifications or substitutes apparent to those skilled in the art fall within the scope of protection of the invention. Therefore, the protected scope of the invention shall be limited only by the scope of protection of the claims.

### REFERENCES

The cited references in this application are incorporated herein by reference in their entirety and are as follows:
[1] Roemer P B, Edelstein W A, Hayes C E, Souza S P, Mueller O M. The NMR phased array. Magn Reson Med 1990; 16(2): 192-225.
[2] Ra J B, Rim C Y. Fast imaging using subencoding data sets from multiple detectors. Magn Reson Med 1993; 30(1): 142-145.
[3] Larkman D J, Nunes R G. Parallel magnetic resonance imaging. Phys Med Biol 2007; 52(7):R15-55.
[4] Pruessmann K P, Weiger M, Scheidegger M B, Boesiger P. SENSE: sensitivity encoding for fast MRI. Magn Reson Med 1999; 42(5):952-962.
[5] Pruessmann K P, Weiger M, Bornert P, Boesiger P. Advances in sensitivity encoding with arbitrary k-space trajectories. Magn Reson Med 2001; 46(4):638-651.
[6] Xie V B, Lyu M, Liu Y, Feng Y, Wu E X. Robust EPI Nyquist ghost removal by incorporating phase error correction with sensitivity encoding (PEC-SENSE). Magn Reson Med 2018; 79(2):943-951.
[7] Willig-Onwuachi J D, Yeh E N, Grant A K, Ohliger M A, Mckenzie C A, Sodickson D K. Phase-constrained parallel M R image reconstruction. J Magn Reson 2005; 176(2):187-198.
[8] Weiger M, Pruessmann K P, Boesiger P. 2D SENSE for faster 3D MRI. Magma 2002; 14(1): 10-19.
[9] Griswold M A, Jakob P M, Heidemann R M, Nittka M, Jellus V, Wang J, Kiefer B, Haase A. Generalized autocalibrating partially parallel acquisitions (GRAPPA). Magn Reson Med 2002; 47(6): 1202-1210.
[10] Sodickson D K, Griswold M A, Jakob P M. SMASH imaging. Magn Reson Imaging Clin N Am 1999; 7(2):237-254, vii-viii.
[11] Mckenzie C A, Ohliger M A, Yeh E N, Price M D, Sodickson D K. Coil-by-coil image reconstruction with SMASH. Magn Reson Med 2001; 46(3):619-623.
[12] Jakob P M, Griswold M A, Edelman R R, Sodickson D K. AUTO-SMASH: a self-calibrating technique for SMASH imaging. Simultaneous Acquisition of Spatial Harmonics. Magma 1998; 7(1):42-54.
[13] Heidemann R M, Griswold M A, Haase A, Jakob P M. V D-AUTO-SMASH imaging. Magn Reson Med 2001; 45(6):1066-1074.
[14] Bydder M, Larkman D J, Hajnal J V. Generalized SMASH imaging. Magn Reson Med 2002; 47(1): 160-170.
[15] Liu Y, Lyu M, Barth M, Yi Z, Leong A T L, Chen F, Feng Y, Wu E X. PEC-GRAPPA reconstruction of simultaneous multislice EPI with slice-dependent 2D Nyquist ghost correction. Magn Reson Med 2019; 81(3): 1924-1934.
[16] Zhang J, Liu C, Moseley M E. Parallel reconstruction using null operations. Magn Reson Med 2011; 66(5):1241-1253.
[17] Shin P J, Larson PEZ, Ohliger M A, Elad M, Pauly J M, Vigneron D B, Lustig M. Calibrationless parallel imaging reconstruction based on structured low-rank matrix completion. Magn Reson Med 2014; 72(4):959-970.
[18] Lustig M, Pauly J M. SPIRIT: Iterative self-consistent parallel imaging reconstruction from arbitrary k-space. Magn Reson Med 2010; 64(2):457-471.
[19] Yi Z, Liu Y, Zhao Y, Xiao L, Leong A T L, Feng Y, Chen F, Wu E X. Joint calibrationless reconstruction of highly undersampled multicontrast M R datasets using a low-rank Hankel tensor completion framework. Magn Reson Med 2021; 85(6):3256-3271.
[20] Liu Y, Yi Z, Zhao Y, Chen F, Feng Y, Guo H, Leong A T L, Wu E X. Calibrationless parallel imaging reconstruction for multislice M R data using low-rank tensor completion. Magn Reson Med 2021; 85(2): 897-911.
[21] Uecker M, Lai P, Murphy M J, Virtue P, Elad M, Pauly J M, Vasanawala S S, Lustig M. ESPIRIT—an eigenvalue approach to autocalibrating parallel MRI: where SENSE meets GRAPPA. Magn Reson Med 2014; 71(3):990-1001.
[22] Tian Y, Adluru G. Dynamic Contrast-Enhanced MRI: Basic Physics, Pulse Sequences, and Modeling. Volume 1; 2020. p 321-344.
[23] Blaimer M, Breuer F, Mueller M, Heidemann R M, Griswold M A, Jakob P M. SMASH, SENSE, PILS, GRAPPA: how to choose the optimal method. Top Magn Reson Imaging 2004; 15(4): 223-236.
[24] Raj A, Singh G, Zabih R, Kressler B, Wang Y, Schuff N, Weiner M. Bayesian parallel imaging with edge-preserving priors. Magn Reson Med 2007; 57(1):8-21.
[25] Block K T, Uecker M, Frahm J. Undersampled radial MRI with multiple coils. Iterative image reconstruction using a total variation constraint. Magn Reson Med 2007; 57(6): 1086-1098.
[26] Jiang M, Jin J, Liu F, Yu Y, Xia L, Wang Y, Crozier S. Sparsity-constrained SENSE reconstruction: An efficient implementation using a fast composite splitting algorithm. Magn Reson Imaging 2013; 31(7):1218-1227.
[27] Hamilton J, Franson D, Seiberlich N. Recent advances in parallel imaging for MRI. Prog Nucl Magn Reson Spectrosc 2017; 101:71-95.
[28] Iyer S, Ong F, Setsompop K, Doneva M, Lustig M. SURE-based automatic parameter selection for ESPIRIT calibration. Magnetic Resonance in Medicine 2020; 84(6):3423-3437.
[29] Hestenes M R, Stiefel E. Methods of Conjugate Gradients for Solving Linear Systems. J Res Natl Bureau Stand 1952; 49(6):409-436.
[30] Plevritis S K, Macovski A. Spectral extrapolation of spatially bounded images [MRI application]. IEEE Trans Med Imaging 1995; 14(3):487-497.
[31] Haldar J P. Low-rank modeling of local k-space neighborhoods (LORAKS) for constrained MRI. IEEE Trans Med Imaging 2014; 33(3):668-681.
[32] Zhao Y, Yi Z, Liu Y, Chen F, Xiao L, Leong A T L, Wu E X. Calibrationless multi-slice Cartesian MRI via orthogonally alternating phase encoding direction and joint low-rank tensor completion. NMR Biomed 2022; 35(7):e4695.
[33] Justin P H. Low-rank modeling of local k-space neighborhoods: from phase and support constraints to structured sparsity. In: ProcSPIE, 2015.
[34] Souza R, Lucena O, Garrafa J, Gobbi D, Saluzzi M, Appenzeller S, Rittner L, Frayne R, Lotufo R. An open, multi-vendor, multi-field-strength brain M R dataset and analysis of publicly available skull stripping methods agreement. NeuroImage 2018; 170:482-494.
[35] Knoll F, Zbontar J, Sriram A, Muckley M J, Bruno M, Defazio A, Parente M, Geras K J, Katsnelson J, Chandarana H, Zhang Z, Drozdzalv M, Romero A, Rabbat M, Vincent P, Pinkerton J, Wang D, Yakubova N, Owens E, Zitnick C L, Recht M P, Sodickson D K, Lui Y W. fastMRI: a publicly available raw k-space and DICOM dataset of knee images for accelerated M R image reconstruction using machine learning. Radiol Artif Intell 2020; 2(1):e190007.
[36] Chen C, Liu Y, Schniter P, Tong M, Zareba K, Simonetti O, Potter L, Ahmad R. OCMR (v1.0)—Open-Access Dataset for Multi-Coil k-Space Data for Cardiovascular Magnetic Resonance Imaging2020.
[37] Buehrer M, Pruessmann K P, Boesiger P, Kozerke S. Array compression for MRI with large coil arrays. Magn Reson Med 2007; 57(6): 1131-1139.
[38] Zhang T, Pauly J M, Vasanawala S S, Lustig M. Coil compression for accelerated imaging with Cartesian sampling. Magn Reson Med 2013; 69(2):571-582.
[39] Wang Z, Bovik A C, Sheikh H R, Simoncelli E P. Image quality assessment: from error visibility to structural similarity. IEEE Trans Image Process 2004; 13(4):600-612.
[40] Knoll F, Holler M, Koesters T, Otazo R, Bredies K, Sodickson D K. Joint M R-PET Reconstruction Using a Multi-Channel Image Regularizer. IEEE transactions on medical imaging 2017; 36(1):1-16.
[41] Bilgic B, Kim T H, Liao C, Manhard M K, Wald L L, Haldar J P, Setsompop K. Improving parallel imaging by jointly reconstructing multi-contrast data. Magn Reson Med 2018; 80(2):619-632.
[42] Chatnuntawech I, Martin A, Bilgic B, Setsompop K, Adalsteinsson E, Schiavi E. Vectorial total generalized variation for accelerated multi-channel multi-contrast MRI. Magn Reson Imaging 2016; 34(8):1161-1170.
[43] Yi Z, Zhao Y, Liu Y, Gao Y, Lyu M, Chen F, Wu E X. Fast Calibrationless Image-space Reconstruction by Structured Low-rank Tensor Estimation of Coil Sensitivity and Spatial Support. In: In Proceedings of the 29th Annual Meeting of ISMRM, Virtual Conference & Exhibition, 2021, p 0067.
[44] Wright K L, Hamilton J I, Griswold M A, Gulani V, Seiberlich N. Non-Cartesian parallel imaging reconstruction. J Magn Reson Imaging 2014; 40(5):1022-1040.
[45] Fessler J A. On NUFFT-based gridding for non-Cartesian MRI. J Magn Reson 2007; 188(2): 191-195.
[46] Fessler J A, Sutton B P. Nonuniform fast Fourier transforms using min-max interpolation. IEEE Transactions on Signal Processing 2003; 51(2):560-574.
[47] Barrett R M, Mw B, Chan T, Jw D, Jm D, Dongarra J, Eijkhout V, Pozo R, Romine C, Van der Vorst H. TEMPLATES for the Solution of Linear Systems: Building Blocks for Iterative Methods 1994.
[48] Peng X, Sutton B P, Lam F, Liang Z-P. DeepSENSE: Learning coil sensitivity functions for SENSE reconstruction using deep learning. Magnetic Resonance in Medicine 2022; 87(4): 1894-1902.
[49] Zhang J, Yi Z, Zhao Y, Xiao L, Hu J, Man C, Wu E X. Calibrationless Reconstruction of Uniformly Undersampled Multi-channel M R data with Deep learning Estimation of ESPIRIT Maps. In: In Proceedings of the 31st Annual Meeting of ISMRM, Virtual Conference & Exhibition, 2022, p 4313.

While the invention is explained in relation to certain embodiments, it is to be understood that various modifications thereof will become apparent to those skilled in the art upon reading the specification. Therefore, it is to be understood that the invention disclosed herein is intended to cover such modifications as fall within the scope of the appended claims.

1. A method for hybrid-domain reconstruction of MRI images, comprising the steps of:
extracting null-subspace bases of a calibration matrix from k-space coil calibration data to directly calculate image-domain spatial null maps (SNMs);
reconstructing multi-channel images by solving an image-domain nulling system formed by SNMs that contain both coil sensitivity and finite image support information, thus circumventing the masking-related procedure and demonstrating a robust reconstruction.

2. The method of claim 1 wherein solving an image-domain nulling system involves combining the image-domain transformations of the null-subspace bases by multiplying the complement of the finite image support and MR images to form the image-domain nulling system.

3. The method of claim 1 further including a step of spatial regularization to reduce noise amplification.

4. The method of claim 1 wherein the spatial nulling maps explicitly represent both coil sensitivity and finite image support information and form an image-domain nulling system for subsequent image reconstruction.

5. A method for reconstruction of MRI images comprising the steps of:
constructing a block-wise Hankel calibration matrix A using central consecutive fully-sampled k-space lines within the multi-channel k-space data, in the matrix the column entries (i.e., vectorized k-space blocks) exhibit strong linear dependencies;
performing the singular value decomposition (SVD), the singular vector matrix V with signal/null-subspace bases of A can be obtained;
setting a cut-off so the signal-subspace spanned by V_{∥} and null-subspace spanned by V_{⊥} are separated;
transforming extracted V_{⊥}, the segment corresponding to the ith channel of each null-subspace basis vⱼ, into a 2D null-subspace convolution kernel fᵢⱼ^{null} through devectorization, each k-space kernel fᵢⱼ^{null} is transformed into an image-domain map sᵢⱼ^{null} through zero-padding and IFFT;
forming an image-domain overdetermined nulling system using sᵢⱼ^{null};
combining multiple sᵢⱼ^{null} to construct multi-channel spatial nulling maps N;
building an image-domain nulling system with N, and
reconstructing multi-channel images by solving the nulling system, specifically, with spatial nulling maps N estimated from the central k-space lines.

6. The method for reconstruction of MRI images according to claim 5 further including incorporation of regularization terms to reduce image noise.

7. The method for reconstruction of MRI images according to claim 5 wherein the spatial nulling maps N contain both coil sensitivity information and finite image support information.

8. A method of extending Cartesian data from the method of claim 1 to non-Cartesian imaging, comprising the steps of:
acquiring non-Cartesian K-space data;
applying nonuniform fast Fourier transform (NUFFT) to estimated Cartesian data;
mixing the non-Cartesian k-space date with the transformed estimated data apply an inversion of NUFFT to the mixed data to obtain current reconstructed images by iteratively solving the nulling system equation;
update spatial nulling maps based on the reconstructed images;
use the updated spatial nulling maps to form updated reconstructed images as the estimated Cartesian data.
